(19) United States
(12) Patent Application Publication
(10) Pub. No.: US 2004/0166691 A1
(43) Pub. Date: Aug. 26, 2004

(54) Method of etching a metal line

(76) Inventors: Chun-Feng Nieh, Hsinchu (TW); Ching-Fan Wang, Hsinchu (TW); Fung-Hsu Cheng, Taoyuan (TW); Zhen-Long Chen, Tainan (TW)

Correspondence Address: BIRCH STEWART KOLASCH & BIRCH, PO BOX 747, FALLS CHURCH, VA, 22040-0747, US

(21) Appl. No.: 10/372,842

(22) Filed: Feb. 26, 2003

(51) Int. Cl. H01L 21/302; H01L 21/461

(52) U.S. Cl. 438/745

(57) ABSTRACT

A method of etching a metal line. A substrate with a metal layer to be etched is provided, on which an amorphous carbon doped layer is formed over the metal layer by plasma enhanced chemical vapor deposition (PECVD). A resist layer is formed over the amorphous carbon doped layer, and the resist layer is patterned to define a resist mask. The amorphous carbon doped layer is etched to define a hardmask, the resist mask is stripped, and the metal layer not covered by the hardmask is etched to form a metal line for forming an interconnect.

### BACKGROUND OF THE INVENTION

1. Field of the Invention

The present invention relates to a BEOL (back end of line) process for fabricating a semiconductor chip, and more specifically to a method of etching a metal line with an amorphous carbon doped layer as a hardmask.

2. Description of the Related Art

In the back end of semiconductor chip fabricating process, the metal systems used to connect the devices and different layers are added to the chip by a process called metallization, comprising forming a dielectric layer over a semiconductor substrate, planarizing and patterning the dielectric layer to form trenches and/or vias, and filling the trenches and/or vias to form conducting wires and/or via plugs. A chemical mechanical polishing process is then performed to planarize the surface of the semiconductor substrate.

It is important to develop a smaller, more powerful semiconductor chip with denser electronic devices and interconnect populations, meaning a metal line with a line width less 180 nm (0.18 μm) is required for the interconnect. Most critical is resolution capability in lithography for the design rule less than 130 nm (0.13 μm). Laser light source of the deep ultraviolet (DUV) spectrum, whose wavelength is equal to or less 248 nm, is used in lithography. A dielectric anti-reflection coating combined with a thinner resist layer can effectively increase small-geometry control in lithography and provide the needed resolution. Etch selectivities of typical metals, such as Al, Ti, and TiN, with respect to the resist material used in DUV lithography are not sufficiently high to permit thinner resist layers to be used alone to etch a metal line.

Instead, a more durable material must be deposited over the metal layer, providing both good anti-reflection for photo patterning and masking function for RIE etching. The hardmask material, having a substantially lower etch rate during RIE, may be deposited relatively thinly and can therefore be more easily patterned with a thin resist mask.

### SUMMARY OF THE INVENTION

Therefore, the main object of the present invention is to provide a method of etching a metal line in BEOL process of 0.13 μm or less.

In order to achieve the above object, the present invention provides a method of etching a metal line, comprising forming an amorphous carbon doped layer as a etching hardmask. First, a substrate with a metal layer to be etched is provided. Then, an amorphous carbon doped layer is formed over the metal layer by plasma enhanced chemical vapor deposition (PECVD). Next, a resist layer is formed over the amorphous carbon doped layer, and patterned to define a resist mask. Next, the amorphous carbon doped layer not covered by the resist mask is etched to define a hardmask. Next, the resist mask is stripped. Further, the metal layer not covered by the hardmask is etched to form a metal line. Finally, the hardmask is ashed using oxygen gas to expose the metal line.

### BRIEF DESCRIPTION OF THE DRAWINGS

The present invention can be more fully understood by reading the subsequent detailed description in conjunction with the examples and references made to the accompanying drawings, wherein:

FIG. 1 through FIG. 8 are cross-sections illustrating manufacturing steps of etching a metal layer comprising forming an amorphous carbon doped layer as a hardmask to form a metal line for 0.13 μm generation or less to form an interconnect in the metal layer in accordance with the preferred embodiment of the present invention.

### DETAILED DESCRIPTION OF THE INVENTION

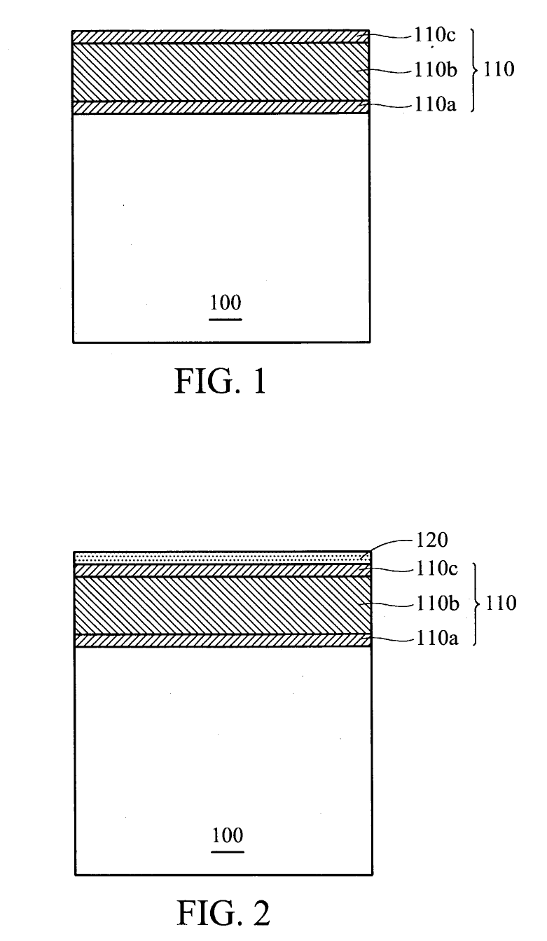

FIG. 1 through FIG. 8 are cross-sections illustrating manufacturing steps of etching a metal line for 0.13 μm generation or less. The method comprises forming an amorphous carbon doped layer as a hardmask to etch a metal line with the present invention.

First, in FIG. 1, a substrate 100 comprising device regions (not shown) is provided. Substrate 100 may further comprise an unfinished interconnect (not shown) over the device regions. As the device regions and unfinished interconnect aforementioned are not significant to the invention, they are not described and shown in detail in order to not unnecessary obscure the present invention. A metal layer 110, such as a three-sub-layered structure consisting of a TiN/Ti sub-layer 110c stacked on an Al subClient's layer 110b on a TiN/Ti sub-layer 110a, is deposited over substrate 100. In the three-sub-layered structure of metal layer 110, TiN/Ti sub-layer 110a is usually about 200 Å to 1000 Å thick, Al sub-layer lob is usually about 3000 Å to 8000 Å thick, usually comprising Cu dissolved in Al with a concentration of approximately 0.5 wt %, and TiN/Ti sub-layer 110c is usually about 250 Å to 1000 Å thick for a process of 0.18 μm generation or less.

Next, in FIG. 2, an amorphous carbon doped layer 120 having a thickness between about 300 and 1000 Å is formed over metal layer 110 by plasma enhanced chemical vapor deposition (PECVD). C₃H₆ gas is used as one precursor ionized by a RF-field with a frequency between about 380 KHZ and about 13.56 MHZ and the ionized carbon particles collide with metal layer 110 at a temperature between 300° C. and 400° C. to form amorphous carbon doped layer 120 over metal layer 110. Note that amorphous carbon doped layer 120 may further serve as an anti-reflective layer in the subsequent patterning step.

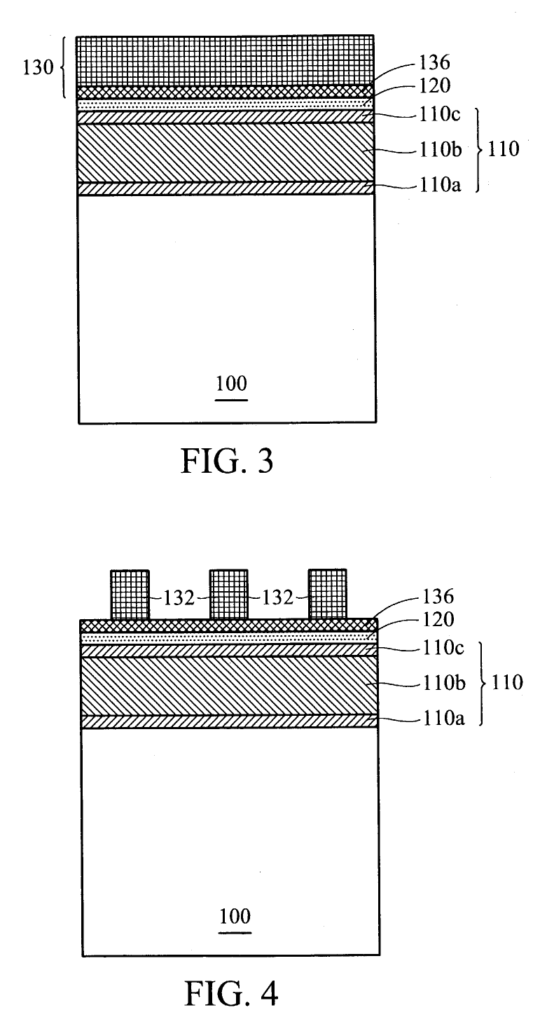

Next, in FIG. 3, resist layer 130 is formed by a method such as spin coating on amorphous carbon doped layer 120. An anti-reflection coating (ARC) layer 136 is optionally provided at the bottom or top of resist layer 130 to combine with amorphous carbon doped layer 120 to assist in limiting reflection in the subsequent patterning step. In the present invention, ARC layer 136 is at the bottom of resist layer 130.

Next, in FIG. 4, resist layer 130 is patterned using a laser light source of the DUV spectrum, with a wavelength equal to or less than 248 nm; resist mask 132 is formed to serve as a mask for etching through ARC layer 136 and amorphous carbon doped layer 120.

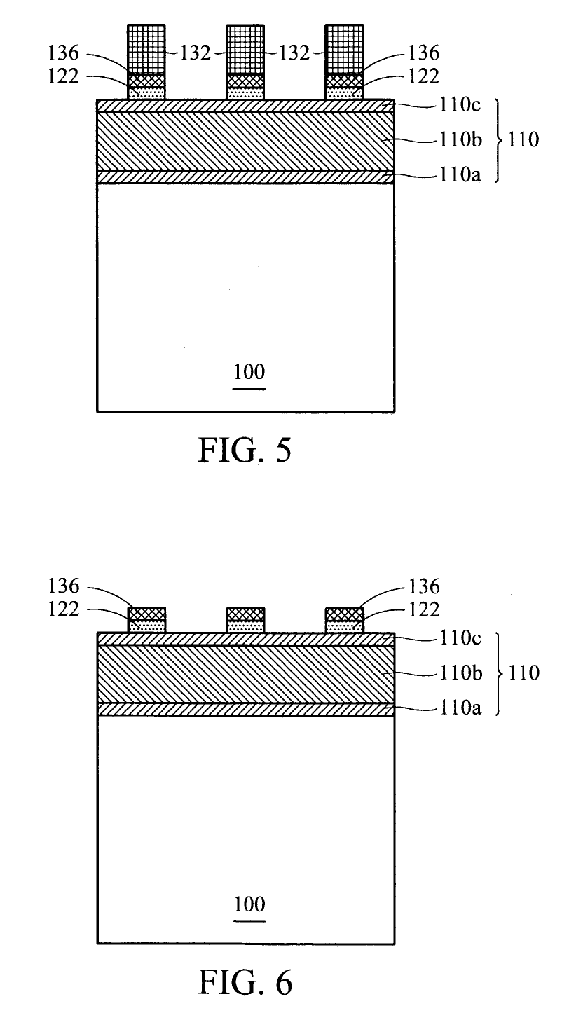

Next, in FIG. 5, a part of ARC layer 136 and amorphous carbon doped layer 120, not covered by resist mask 122, is etched by the plasma containing oxygen ions. The remained amorphous carbon doped layer 120 functions as hardmask 122 for etching metal layer 110.

Next, in FIG. 6, resist mask 132 is stripped to expose ARC layer 136.

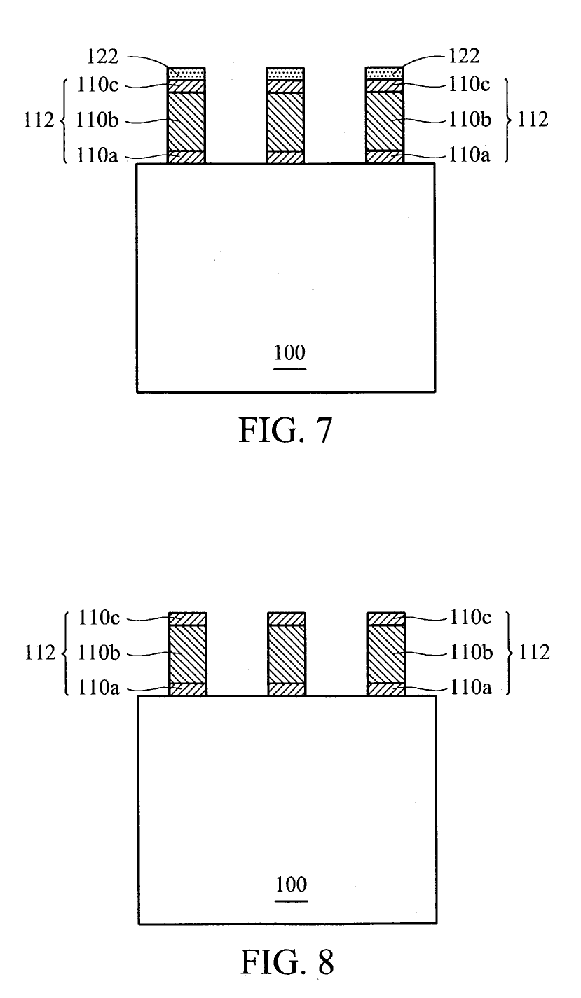

Next, in FIG. 7, a part of metal layer 110, not covered by hardmask 122, is etched by RIE using a fluorine-containing gas such as CF₄ at a pressure between about 10 mT to 150 mT at power between about 100 watts to 1500 watts. ARC layer 136 is removed and hardmask 122 functions as the mask to transform a predetermined pattern with a line width as low as 0.13 μm or less to metal layer 110 during the etching of metal layer 110. Metal line 112 is therefore formed with a line width as low as 0.13 μm or less.

Finally, in FIG. 8, hardmask 122 is ashed using oxygen gas to expose the metal line 112.

The main advantage provided by the present invention is reduction of the width of the metal line to form an interconnect. The width of the metal line can be reduced to as low as 0.13 μm or less, thereby achieving the main object of the present invention.

Although the present invention has been particularly shown and described above with reference to the preferred specific embodiments, it is anticipated that alterations and modifications thereof will no doubt become apparent to those skilled in the art. It is therefore intended that the following claims be interpreted as covering all such alteration and modifications as fall within the true spirit and scope of the present invention.

What is claimed is:

1. A method of etching a metal line, comprising:
providing a substrate with a metal layer to be etched;
forming an amorphous carbon doped layer over the metal layer;
forming a resist layer over the amorphous carbon doped layer;
patterning the resist layer to define a resist mask;
etching the amorphous carbon doped layer not covered by the resist mask to define a hardmask;
stripping the resist mask; and
etching the metal layer not covered by the hardmask to form a metal line.

2. The method as claimed in claim 1, further comprising ashing the hardmask to expose the metal line after the metal line is formed.

3. The method as claimed in claim 1, wherein the metal layer comprises a three-sub-layer, having a second TiN/Ti sub-layer stacked on an Al sub-layer on a first TiN/Ti sub-layer.

4. The method as claimed in claim 3, wherein the Al sub-layer further comprises Cu dissolved in Al at a concentration of approximately 0.5 wt %.

5. The method as claimed in claim 3, wherein the thickness of the first TiN/Ti sub-layer is between about 200 and 1000 Å, the thickness of the Al sub-layer is between about 3000 and 8000 Å, and the thickness of the first TiN/Ti sub-layer is between about 250 and 1000 Å.

6. The method as claimed in claim 1, wherein the thickness of the amorphous carbon doped layer is between about 300 and 1000 Å.

7. The method as claimed in claim 1, further comprising forming an anti-reflection coating (ARC) layer after the amorphous carbon doped layer is deposited.

8. The method as claimed in claim 1, wherein the resist mask is patterned by light with a wavelength equal to or less than about 248 nm.

9. A method of etching a metal line, comprising:
providing a substrate with a metal layer, having a three-sub-layered layer having a second TiN/Ti sub-layer stacked on an Al-(approximately 0.5 wt %)Cu alloy sub-layer on a first TiN/Ti sub-layer, to be etched;
forming an amorphous carbon doped layer over the metal layer;
forming a resist layer over the amorphous carbon doped layer;
patterning the resist layer to define a resist mask;
etching the amorphous carbon doped layer not covered by the resist mask to define a hardmask;
stripping the resist mask;
etching the metal layer not covered by the hardmask to form a metal line; and
ashing the hardmask to expose the metal line.

10. The method as claimed in claim 9, wherein the thickness of the first TiN/Ti sub-layer is between about 200 and 1000 Å, the thickness of the Al-(approximately 0.5 wt %)Cu alloy sub-layer is between about 3000 and 8000 Å, and the thickness of the first TiN/Ti sub-layer is between about 250 and 1000 Å.

11. The method as claimed in claim 9, wherein the thickness of the amorphous carbon doped layer is between about 300 and 1000 Å.

12. The method as claimed in claim 9, further comprising forming an anti-reflection coating (ARC) layer after the amorphous carbon doped layer is deposited.

13. The method as claimed in claim 9, wherein the resist mask is patterned by light with a wavelength equal to or less than about 248 nm.
